(19) United States
(12) Patent Application Publication
(10) Pub. No.: US 2021/0288459 A1
(43) Pub. Date: Sep. 16, 2021

(54) LASER SYSTEM AND ELECTRONIC DEVICE MANUFACTURING METHOD

(71) Applicant: Gigaphoton Inc., Tochigi (JP)

(72) Inventors: Yuki TAMARU, Oyama-shi (JP); Taisuke MIURA, Oyama-shi (JP)

(73) Assignee: Gigaphoton Inc., Tochigi (JP)

(21) Appl. No.: 17/337,906

(22) Filed: Jun. 3, 2021

Related U.S. Application Data
(63) Continuation of application No. PCT/JP2019/002058, filed on Jan. 23, 2019.

(51) Int. Cl. H01S 3/038; H01S 3/02

(52) U.S. Cl. CPC H01S 3/038; H01S 3/025

(57) ABSTRACT

A laser system includes a random phase plate in an optical path between a solid-state laser device and an excimer amplifier. Cells of a predetermined shape are periodically arranged on the plate, each cell being a minimum unit region of an irregular pattern, regions of depressions or projections in units of the cells being randomly arranged. When a traveling direction of a laser beam is a Z direction, a discharge direction is a V direction, a direction orthogonal to the V and Z directions is an H direction, an in-plane direction of the plate corresponding to the V direction is a first direction, an in-plane direction of the plate corresponding to the H direction is a second direction, lengths of the cell are d1 in the first direction and d2 in the second direction, an aspect ratio of the cell defined by d2/d1 is 1.2 or more.

### CROSS-REFERENCE TO RELATED APPLICATIONS

The present application is a continuation application of International Application No. PCT/JP2019/002058, filed on Jan. 23, 2019, the entire contents of which are hereby incorporated by reference.

### BACKGROUND

### 1. Technical Field

The present disclosure relates to a laser system and an electronic device manufacturing method.

### 2. Related Art

Improvement in resolution of semiconductor exposure apparatuses (hereinafter simply referred to as “exposure apparatuses”) has been desired due to miniaturization and high integration of semiconductor integrated circuits. For this purpose, exposure light sources that output light with shorter wavelengths have been developed. As the exposure light source, a gas laser apparatus is used in place of a conventional mercury lamp. As a gas laser apparatus for exposure, a KrF excimer laser apparatus that outputs ultraviolet light having a wavelength of 248 nm and an ArF excimer laser apparatus that outputs ultraviolet light having a wavelength of 193 nm are currently used.

As current exposure technology, immersion exposure is practically used in which a gap between a projection lens of an exposure apparatus and a wafer is filled with a liquid and a refractive index of the gap is changed to reduce an apparent wavelength of light from an exposure light source. When the immersion exposure is performed using the ArF excimer laser apparatus as the exposure light source, the wafer is irradiated with ultraviolet light having an equivalent wavelength of 134 nm. This technology is referred to as ArF immersion exposure (or ArF immersion lithography).

The KrF excimer laser apparatus and the ArF excimer laser apparatus have a large spectral line width of about 350 to 400 pm in natural oscillation. Thus, chromatic aberration of a laser beam (ultraviolet light), which is reduced and projected on a wafer by a projection lens of an exposure apparatus, occurs to reduce resolution. Then, a spectral line width (also referred to as a spectral width) of a laser beam output from the gas laser apparatus needs to be narrowed to the extent that the chromatic aberration can be ignored. For this purpose, a line narrowing module (LNM) having a line narrowing element is provided in a laser resonator of the gas laser apparatus to narrow the spectral width. The line narrowing element may be etalon, grating, or the like. A laser apparatus with such a narrowed spectral width is referred to as a line narrowing laser apparatus.

### LIST OF DOCUMENTS

### Patent Documents

Patent Document 1: Japanese Unexamined Patent Application Publication No. 2011-192849

Patent Document 2: Japanese Unexamined Patent Application Publication No. 2013-141029

Patent Document 3: Japanese Unexamined Patent Application Publication No. 61-243403

Patent Document 4: Japanese Unexamined Patent Application Publication No. 2008-140980

### SUMMARY

A laser system according to one aspect of the present disclosure includes a solid-state laser device configured to output a laser beam; an excimer amplifier including a pair of discharge electrodes arranged to face each other with a discharge space therebetween, the laser beam passing through the discharge space, the excimer amplifier being configured to amplify the laser beam; and a random phase plate arranged in an optical path between the solid-state laser device and the excimer amplifier, cells of a predetermined shape being periodically arranged on the random phase plate, each cell being a minimum unit region of an irregular pattern that provides a phase difference to the laser beam, regions of depressions or projections in units of the cells being randomly arranged, when a traveling direction of the laser beam entering the excimer amplifier is a Z direction, a discharge direction of the discharge electrodes is a V direction, a direction orthogonal to the V direction and the Z direction is an H direction, an in-plane direction of the random phase plate corresponding to the V direction of a beam section of the laser beam entering the excimer amplifier is a first direction, an in-plane direction of the random phase plate corresponding to the H direction of the beam section is a second direction, a length of the cell in the first direction is d1, and a length of the cell in the second direction is d2, an aspect ratio of the cell defined by d2/d1 being 1.2 or more.

An electronic device manufacturing method according to another aspect of the present disclosure includes generating an excimer laser beam with a laser system, the laser system including a solid-state laser device configured to output a laser beam, an excimer amplifier including a pair of discharge electrodes arranged to face each other with a discharge space therebetween, the laser beam passing through the discharge space, the excimer amplifier being configured to amplify the laser beam, and a random phase plate arranged in an optical path between the solid-state laser device and the excimer amplifier, cells of a predetermined shape being periodically arranged on the random phase plate, each cell being a minimum unit region of an irregular pattern that provides a phase difference to the laser beam, regions of depressions or projections in units of the cells being randomly arranged, when a traveling direction of the laser beam entering the excimer amplifier is a Z direction, a discharge direction of the discharge electrodes is a V direction, a direction orthogonal to the V direction and the Z direction is an H direction, an in-plane direction of the random phase plate corresponding to the V direction of a beam section of the laser beam entering the excimer amplifier is a first direction, an in-plane direction of the random phase plate corresponding to the H direction of the beam section is a second direction, a length of the cell in the first direction is d1, and a length of the cell in the second direction is d2, an aspect ratio of the cell defined by d2/d1 being 1.2 or more; outputting the excimer laser beam to an exposure apparatus; and exposing the excimer laser beam onto a photosensitive substrate within the exposure apparatus to manufacture an electronic device.

### BRIEF DESCRIPTION OF THE DRAWINGS

With reference to the accompanying drawings, some embodiments of the present disclosure will be described below merely by way of example.

FIG. 1 shows an example of a cell on a random phase plate.

FIG. 2 schematically shows an exemplary configuration of a laser system.

FIG. 3 schematically shows a configuration of a laser system according to Embodiment 1.

FIG. 4 is a diagrammatic front view of an example of a random phase plate.

FIG. 5 diagrammatically illustrates a function of the random phase plate.

FIG. 6 collectively shows diagrams of beam profiles and beam divergences of a current excimer laser apparatus and various hybrid laser apparatuses.

FIG. 7 is a diagrammatic front view of another example of the random phase plate.

FIG. 8 schematically shows a configuration of a laser system according to Embodiment 2.

FIG. 9 schematically shows a configuration of a laser system according to Embodiment 3.

FIG. 10 schematically shows a configuration of a laser system according to Embodiment 4.

FIG. 11 schematically shows an exemplary configuration of an exposure apparatus.

### DESCRIPTION OF EMBODIMENTS

### Contents

1. Terms
2. Overview of laser system
   2.1 Configuration
   2.2 Operation
3. Problem
4. Embodiment 1
   4.1 Configuration
   4.1.1 Example 1 of random phase plate
   4.2 Operation
   4.3 Effect
   4.4 Another example of random phase plate
   4.4.1 Example 2 of random phase plate
   4.4.2 Shape of cell
5. Embodiment 2
   5.1 Configuration
   5.2 Operation
   5.3 Effect
6. Embodiment 3
   6.1 Configuration
   6.2 Operation
   6.3 Effect
7. Embodiment 4
   7.1 Configuration
   7.2 Operation
   7.3 Effect
8. Electronic device manufacturing method
9. Others

Now, with reference to the drawings, embodiments of the present disclosure will be described in detail. The embodiments described below illustrate some examples of the present disclosure, and do not limit contents of the present disclosure. Also, all configurations and operations described in the embodiments are not necessarily essential as configurations and operations of the present disclosure. The same components are denoted by the same reference numerals, and overlapping descriptions are omitted.

### 1. Terms

Terms used herein are defined as described below.

“Hybrid laser apparatus” refers to a two-stage laser apparatus including an oscillation stage (master oscillator) and an amplification stage (amplifier), the oscillation stage including a solid-state laser device and the amplification stage including an excimer laser apparatus. “Excimer amplifier” refers to an excimer laser apparatus used in the amplification stage.

A traveling direction of a laser beam is herein defined as “Z direction”. One direction perpendicular to the Z direction is defined as “H direction”, and a direction perpendicular to the H direction and the Z direction is defined as “V direction”. For example, a traveling direction of the laser beam entering the excimer amplifier may be the Z direction, and a direction of a pair of discharge electrodes facing each other in the excimer amplifier, that is, a discharge direction may be the V direction.

“Cell” on a random phase plate refers to a minimum unit region of a predetermined shape, which is a region of a depression or a projection of an irregular pattern that provides a phase difference to the beam. A plurality of cells are periodically arranged in an element surface of the random phase plate. “Periodically” herein refers to the cells being spatially regularly arranged in a specific repeated pattern. Specifically, the element surface of the random phase plate is divided into the cells, and each cell is formed as a region of a depression or a projection. In the element surface of the random phase plate, regions of depressions or projections in units of the cells are spatially randomly arranged.

For the shape of the cell, “aspect ratio” is defined as descried below. Specifically, when a first direction and a second direction orthogonal to the first direction are defined in a plane parallel to the element surface of the random phase plate, a length of the cell in the first direction is d1, and a length of the cell in the second direction is d2, d2/d1 is defined as an aspect ratio.

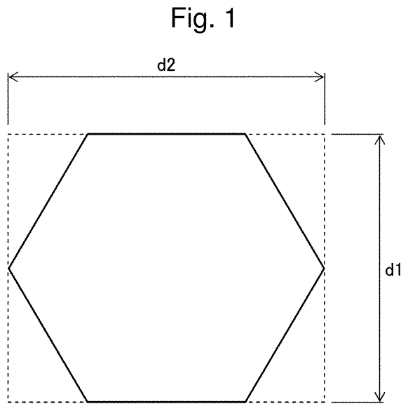

FIG. 1 shows an example of a hexagonal cell. In FIG. 1, a vertical direction is the first direction and a transverse direction is the second direction. The length d1 of the cell in the first direction is a distance between first circumscribed parallel lines parallel to the second direction with respect to an outline of the cell. The length d2 of the cell in the second direction is a distance between second circumscribed parallel lines parallel to the first direction with respect to the outline of the cell.

The first direction is specified by a relationship with the discharge direction (V direction) of the excimer amplifier. The first direction corresponds to the V direction, and the second direction corresponds to the H direction. “Corresponding direction” refers to relatively the same direction in a beam section at each of different positions in an optical path. For example, if a mirror or the like that changes the traveling direction of the laser beam exists in the optical path between the random phase plate and the excimer amplifier, there may be a case that the first direction of the random phase plate is different from the discharge direction of the excimer amplifier. However, it is understood that the first direction in the beam section of the laser beam emitted from the random phase plate is relatively the same as the V direction in the beam section of the laser beam entering the excimer amplifier.

If the mirror or the like that changes the traveling direction of the laser beam does not exist in the optical path between the random phase plate and the excimer amplifier, and the laser beam emitted from the random phase plate enters the excimer amplifier while maintaining the first direction in the beam section of the laser beam, the first direction may be parallel to the V direction.

The term “parallel” herein may include the concept of “substantially parallel” that may be considered to be substantially equivalent to “parallel” in technical significance. Also, the term “perpendicular” or “orthogonal” may include the concept of “substantially perpendicular” or “substantially orthogonal” that may be considered to be substantially equivalent to “perpendicular” or “orthogonal” in technical significance.

### 2. Overview of Laser System

2.1 Configuration

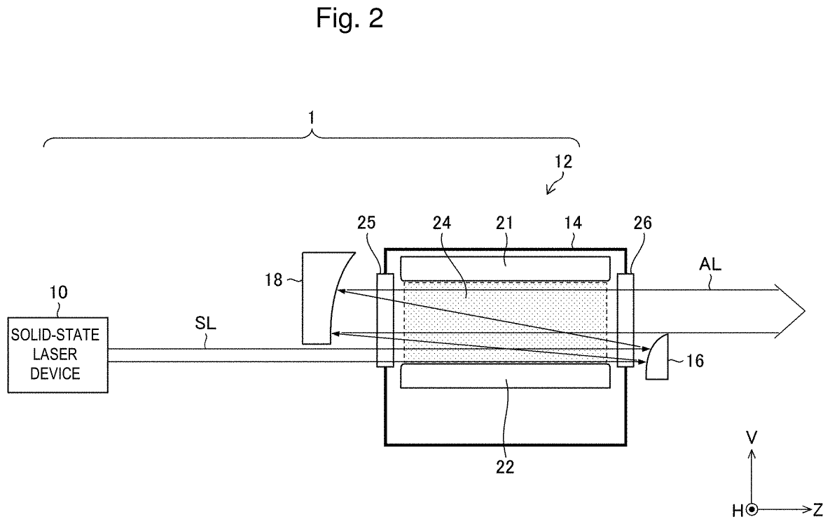

FIG. 2 schematically shows an exemplary configuration of a laser system 1. The laser system 1 is a hybrid laser apparatus including a solid-state laser device 10 and an excimer amplifier 12. The solid-state laser device 10 is an ultraviolet solid-state laser device that outputs, as seed light SL, an ultraviolet pulse laser beam having a wavelength of about 193.4 nm. The solid-state laser device 10 may include, for example, a semiconductor laser, a semiconductor amplifier, an optical fiber amplifier, and a wavelength conversion system using a nonlinear crystal.

The solid-state laser device 10 is arranged such that the seed light SL output from the solid-state laser device 10 and having the wavelength of about 193.4 nm enters the excimer amplifier 12. An optical element such as a highly reflective mirror (not shown) may be arranged in an optical path between the solid-state laser device 10 and the excimer amplifier 12.

The excimer amplifier 12 includes a chamber 14, a convex cylindrical mirror 16, and a concave cylindrical mirror 18. The chamber 14 contains, for example, an ArF laser gas containing an Ar gas as a noble gas, an F₂ gas as a halogen gas, and an Ne gas as a buffer gas.

A pair of discharge electrodes 21, 22 are arranged to face each other with a discharge space 24 therebetween in a V direction in the chamber 14. The V direction is parallel to a vertical direction of the plane of FIG. 2. The V direction corresponds to a discharge direction. A high voltage pulse power source (not shown) is arranged outside the chamber 14. The high voltage pulse power source is electrically connected to the discharge electrodes 21, 22 arranged in the chamber 14.

The chamber 14 includes windows 25, 26 that transmit a laser beam having a wavelength of about 193.4 nm. The window 25 is an entrance window through which the seed light SL output from the solid-state laser device 10 first enters the chamber 14. The window 26 is an exit window through which an amplified laser beam AL that is the amplified seed light SL is finally emitted from the chamber 14. The amplified laser beam AL is emitted through the window 26 in a Z direction perpendicular to the V direction. The Z direction is parallel to a transverse direction of the plane of FIG. 2.

The windows 25, 26 are tilted with respect to a discharge surface of the discharge electrodes 21, 22. The discharge surface is parallel to the plane of FIG. 2 (V-Z plane).

A convex reflective surface of the convex cylindrical mirror 16 and a concave reflective surface of the concave cylindrical mirror 18 are coated with highly reflective films that highly reflect the beam having the wavelength of about 193.4 nm. The convex cylindrical mirror 16 and the concave cylindrical mirror 18 are arranged to allow the seed light SL output from the solid-state laser device 10 and having the wavelength of 193.4 nm to pass three times through the discharge space 24. Thus, the seed light SL is expanded in the discharge direction and amplified in the discharge space 24.

2.2 Operation

The seed light SL output from the solid-state laser device 10 and having the wavelength of about 193.4 nm passes below a lower end of the concave cylindrical mirror 18, and enters the discharge space 24 while travelling parallel to longitudinal axes of the discharge electrodes 21, 22. The “longitudinal axes” of the discharge electrodes 21, 22 refer to axes of the discharge electrodes 21, 22 in a longitudinal direction, and may be in the Z direction in FIG. 2.

The seed light SL traveling parallel to the longitudinal axes of the discharge electrodes 21, 22 in the discharge space 24 is amplified and enters the convex cylindrical mirror 16. The seed light SL highly reflected by the convex cylindrical mirror 16 passes through the discharge space 24 while being expanded in the discharge direction, and is thus further amplified and enters the concave cylindrical mirror 18.

The seed light SL having entered the concave cylindrical mirror 18 is highly reflected and collimated with respect to the longitudinal axes of the discharge electrodes 21, 22 by the concave cylindrical mirror 18, again passes through the discharge space 24, and is further amplified. The amplified laser beam AL collimated by the concave cylindrical mirror 18 and amplified passes above an upper end of the convex cylindrical mirror 16 and is emitted from the laser system 1. The amplified laser beam AL emitted from the laser system 1 enters an exposure apparatus (not shown in FIG. 2).

### 3. Problem

In a current typical laser apparatus for an exposure apparatus, a gas laser device using an excimer laser gas as a laser medium is used on each of an oscillation stage (master oscillator) and an amplification stage (amplifier). However, a discharge-excited excimer laser apparatus has lower beam quality than a solid-state laser device due to its characteristic, and the beam emitted from the discharge-excited excimer laser apparatus has beam divergence (beam divergence angle) significantly different between a vertical direction and a transverse direction. Here, the vertical direction is a discharge direction, and the transverse direction is orthogonal to the discharge direction and orthogonal to a traveling direction of a laser beam. The vertical direction is referred to as a V direction, and the transverse direction is referred to as an H direction.

On the other hand, in the laser system 1 in FIG. 2, the excimer amplifier 12 directly amplifies the seed light SL output from the solid-state laser device 10 with higher coherence than the discharge-excited excimer laser apparatus, thereby obtaining an amplified laser beam AL with higher beam quality, that is, with smaller beam divergence (beam divergence angle).

Considering that the hybrid laser apparatus having the configuration in FIG. 2 is connected to an exposure apparatus for use in place of the current discharge-excited excimer laser apparatus, beam divergence of the current excimer laser apparatus is different from beam divergence of the hybrid laser system, which may cause Problems 1 and 2 below.

### [Problem 1]

Vignetting in an optical path occurs in the exposure apparatus, which affects throughput or the like.

### [Problem 2]

A beam characteristic of the amplified laser beam AL output from the laser system 1 is different from a beam characteristic of the laser beam output from the current excimer laser apparatus, which may cause a problem that unnecessary light condensing occurs in the exposure apparatus to damage an optical element, or the like.

### 4. Embodiment 1

4.1 Configuration

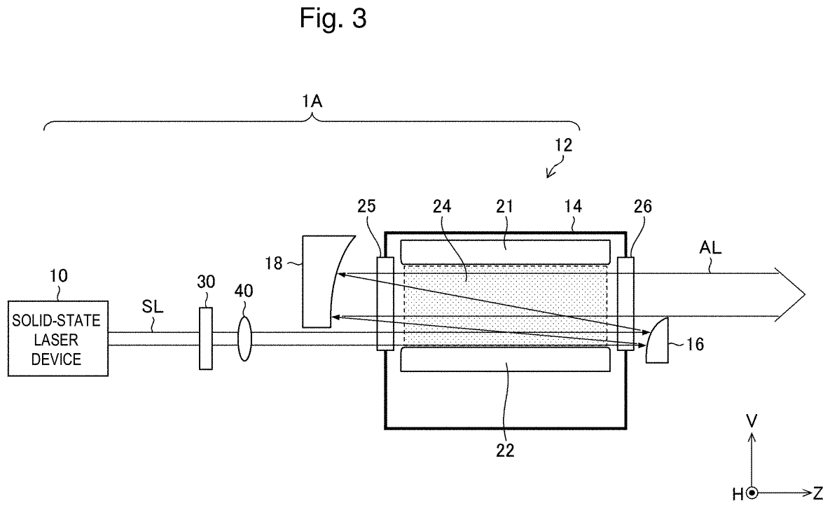

FIG. 3 schematically shows a configuration of a laser system 1A according to Embodiment 1. Differences from the laser system 1 in FIG. 2 will be described. The laser system 1A according to Embodiment 1 in FIG. 3 includes a random phase plate 30 and a convex lens 40 in an optical path between a solid-state laser device 10 and an excimer amplifier 12.

The random phase plate 30 is a transmission optical element, and on one surface of a light transmissive substrate thereof, minute cells of a predetermined shape with a phase difference of π radian (half wavelength) are randomly two-dimensionally arranged. Specifically, the random phase plate 30 is coated with a film with each cell being a minimum unit, and depressions and projections formed by the film are randomly two-dimensionally arranged in a plane of the light transmissive substrate.

A surface of the random phase plate 30 which a laser beam (seed light SL) output from the solid-state laser device 10 enters is referred to as “first surface”, and a surface from which the laser beam having passed through the random phase plate 30 is emitted is referred to as “second surface”. On the second surface of the random phase plate 30 in this example, an irregular pattern in which depressions and projections are spatially randomly two-dimensionally arranged is formed, each of the depressions and the projections being a minute cell of a predetermined shape as a minimum unit. The irregular pattern may be formed on the first surface of the random phase plate 30.

The convex lens 40 is arranged in the optical path between the random phase plate 30 and the excimer amplifier 12. The convex lens 40 is arranged such that the beam having passed through the random phase plate 30 enters the convex lens 40. The convex lens 40 condenses the beam having passed through the random phase plate 30 and causes the beam to enter the excimer amplifier 12. The convex lens 40 is an example of “light condensing optical system” in the present disclosure. A light condensing mirror may be arranged in place of the convex lens 40.

The excimer amplifier 12 in FIG. 3 is an example of “three-pass amplifier” in the present disclosure. The convex cylindrical mirror 16 is an example of “first mirror” and “convex mirror” in the present disclosure. The concave cylindrical mirror 18 is an example of “second mirror” in the present disclosure.

4.1.1 Example 1 of Random Phase Plate

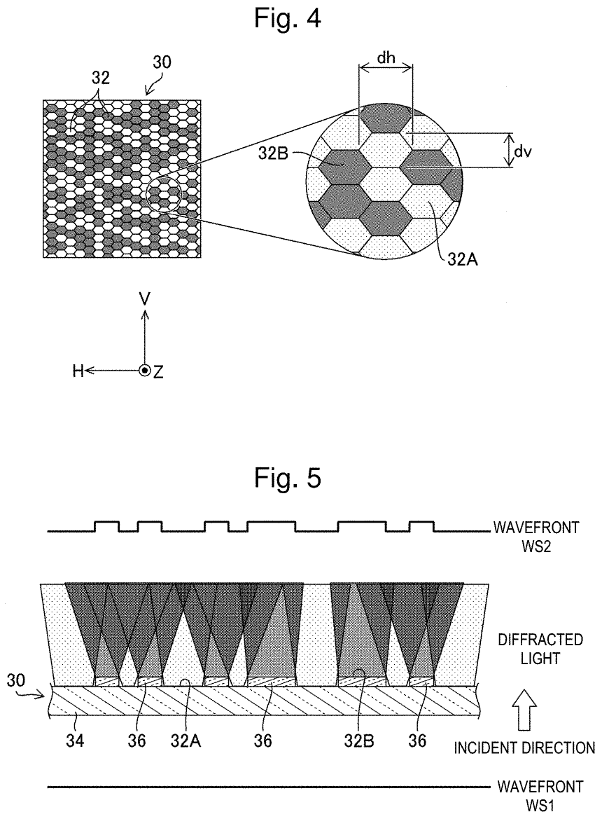

FIG. 4 is a diagrammatic front view of an example of the random phase plate 30. FIG. 4 includes a partially enlarged diagram of the irregular pattern provided on the second surface of the random phase plate 30. FIG. 4 shows an example of a hexagonal cell 32. In the laser system 1A according to Embodiment 1, a vertical direction of the random phase plate 30 matches a vertical direction (V direction) of the excimer amplifier 12.

In an element surface of the random phase plate 30, a plurality of cells 32 are periodically arranged in an H direction and the V direction. The cells 32 are herein arranged as divided regions in design which is specified in production of the random phase plate 30. The cells 32 periodically arranged are formed as regions of depressions 32A or projections 32B that provide a phase difference to the beam, and the depressions 32A and the projections 32B are spatially randomly arranged in the element surface in units of the cells 32.

The random phase plate 30 can split an entering beam into fine beams in units of the cells 32. The random phase plate 30 is designed to have a level difference between a depression 32A and a projection 32B such that a phase difference between a fine beam having passed through the depression 32A and a fine beam having passed through the projection 32B is, for example, π radian.

The cell 32 that is a minimum unit region of the irregular pattern that provides a phase difference to a split fine beam has a so-called horizontally long shape with a length dh in the H direction being longer than a length dv in the V direction, and has an aspect ratio defined by dh/dv of 1.2 or more. The value of “1.2” is larger than an aspect ratio of a regular hexagon. A range of the aspect ratio of the cell 32 is preferably 1.2 or more and 5.0 or less, and more preferably 2.0 or more and 3.0 or less.

For a size of the cell 32, for example, a preferable range of the length dh of the cell 32 in the longitudinal direction (H direction) is 20 μm or more and 500 μm or less. The length dh of the cell 32 in the H direction may be taken as a distance between the periodically arranged cells 32 in the H direction. The length dv of the cell 32 in the V direction may be taken as a distance between the arranged cells 32 in the V direction.

As shown in FIG. 4, the random phase plate 30 is arranged in the optical path with a long axis of the cell 32 in the H direction and a short axis in the V direction. In other words, the random phase plate 30 is arranged in the optical path such that a direction with a fine irregular pattern in the element surface is the V direction and a direction with a coarse irregular pattern is the H direction.

As shown in FIG. 5, the random phase plate 30 has a structure in which, for example, films 36 are arranged on a surface of the light transmissive substrate 34, a region of the cell 32 provided with the film 36 is formed as the projection 32B, and a region of the cell 32 without the film 36 is formed as the depression 32A.

A material for the light transmissive substrate 34 is, for example, at least one of synthetic quartz, crystal, and calcium fluoride. A material for the film 36 is, for example, at least one of SiO₂, MgF₂, AlF₃, Na₃AlF₆, Na₅Al₃F₁₄, GdF₂, GdF₃, LaF₃, LaF₂, NdF₃, DyF₃, and YF₃.

The projection 32B and the depression 32A may be formed by varying a thickness of a film in units of the cells 32, not limited to formed by providing or not providing the films 36.

An in-plane direction parallel to the element surface (H-V plane) of the random phase plate 30 in FIG. 4 is an example of “in-plane direction of random phase plate” in the present disclosure. Also, the length dv in the V direction in FIG. 4 is an example of “length d1 in the first direction” in the present disclosure, and the length dh in the H direction is an example of “length d2 in the second direction” in the present disclosure.

4.2 Operation

FIG. 5 diagrammatically illustrates a function of the random phase plate 30. The laser beam enters the random phase plate 30 from a bottom side in FIG. 5, and the laser beam having passed through the random phase plate 30 is emitted toward a top side in FIG. 5.

A wavefront WS1 of the laser beam entering the random phase plate 30 has a constant phase. FIG. 5 shows the constant phase of the wavefront WS1 by a straight line.

The random phase plate 30 splits the laser beam entering the first surface into a plurality of beams according to the shapes of the regions of the depression 32A and the projection 32B. Then, the random phase plate 30 provides a phase difference π between the fine beam having passed through the depression 32A and the fine beam having passed through the projection 32B. Given that the phase of the fine beam having passed through the depression 32A is “0 phase” and the phase of the fine beam having passed through the projection 32B is “π phase”, the beam having passed through the random phase plate 30 travels with the fine beams of the two types of phases being superimposed.

Thus, a wavefront WS2 of the laser beam emitted from the random phase plate 30 has a spatially random phase difference due to the irregular pattern of the depression 32A and the projection 32B. In FIG. 5, a pattern of the phase difference reflecting the shape of the irregular pattern of the random phase plate 30 is shown by the wavefront WS2.

The fine beam passing through the depression 32A and the fine beam passing through the projection 32B each travel as diffracted light having a diffracting angle according to a size of the region of the depression 32A or the projection 32B.

The diffracting angle is larger for a smaller depression 32A or projection 32B. Since the aspect ratio of the cell 32 on the random phase plate 30 is 1.2 or more, the diffracting angle differs between the vertical direction (V direction) and the transverse direction (H direction). Specifically, the diffracting angle in the vertical direction is larger than the diffracting angle in the transverse direction.

Using such a random phase plate 30 allows change of a length-to-width ratio of beam divergence of the laser beam (seed light SL) entering the excimer amplifier 12.

Also, the fine beam of “0 phase” and the fine beam of “π phase” of the laser beam having passed through the random phase plate 30 do not interfere with each other, and thus a light intensity distribution in a beam section at a focal point of the convex lens 40 is not a Gaussian distribution but nearly a top-hat distribution.

As a result, beam quality of the laser beam entering the excimer amplifier 12 can be close to beam quality of a current excimer laser apparatus.

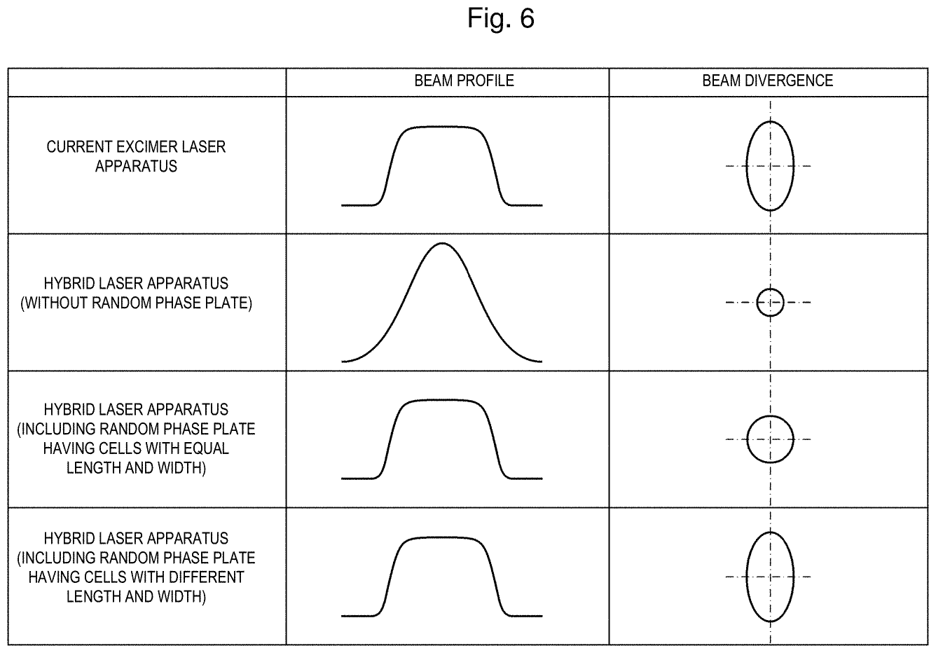

FIG. 6 collectively shows diagrams of beam profiles and beam divergences of a current excimer laser apparatus and various hybrid laser apparatuses.

For comparison, four types of devices are shown: a current excimer laser apparatus, a hybrid laser apparatus without a random phase plate, a hybrid laser apparatus including a random phase plate having cells with equal length and width, and a hybrid laser apparatus including a random phase plate having cells with different length and width.

“Hybrid laser apparatus without a random phase plate” refers to a configuration of the laser system 1 as described with reference to FIG. 1. “Random phase plate having cells with equal length and width” refers to a random phase plate having an aspect ratio of a cell of 1.0. “Random phase plate having cells with different length and width” refers to a random phase plate having an aspect ratio of a cell of 1.2 or more as illustrated in FIGS. 4 and 5. The beam profile and the beam divergence of the laser system 1A according to Embodiment 1 are those of “hybrid laser apparatus (including a random phase plate having cells with different length and width)” shown at the bottom in FIG. 6.

The beam profile and the beam divergence of each device in FIG. 6 may be taken as a beam profile and beam divergence of a laser beam amplified by the excimer amplifier, or as a beam profile and beam divergence of a laser beam entering the excimer amplifier (unamplified seed light).

The beam profile of the current excimer laser apparatus is a top-hat distribution, and the beam divergence is larger in the V direction than in the H direction. The beam profile of the hybrid laser apparatus without a random phase plate is a Gaussian distribution, and the beam divergence is small in both the H direction and the V direction and isotropic.

The beam profile of the hybrid laser apparatus including a random phase plate having cells with equal length and width is a top-hat distribution, and the beam divergence is larger in both the H direction and the V direction as compared to that of the hybrid laser apparatus without a random phase plate, but is isotropic without any change in length-to-width ratio.

The beam profile of the hybrid laser apparatus including a random phase plate having cells with different length and width, such as the laser system 1A according to Embodiment 1, is a top-hat distribution, and the beam divergence is larger in both the H direction and the V direction and larger in the V direction than in the H direction as compared to that of the hybrid laser apparatus without a random phase plate. Specifically, using the random phase plate having cells with different length and width can achieve a beam profile and beam divergence close to those of the current excimer laser apparatus.

The shape of the cell 32 on the random phase plate 30 can be designed for a target beam profile and target beam divergence. Specifically, changing the shape of the cell 32 on the random phase plate 30 can achieve a desired beam profile and desired beam divergence.

Also, the convex lens 40 is arranged between the random phase plate 30 and the excimer amplifier 12 to allow the laser beam to appropriately propagate into the three-pass amplifier.

4.3 Effect

With the laser system 1A according to Embodiment 1, the random phase plate 30 provides different diffracting angles in the V direction and the H direction, thereby allowing change of the length-to-width ratio of the beam divergence. This allows generation of an excimer laser beam having a beam characteristic close to that of the excimer laser beam generated by the current excimer laser apparatus.

4.4 Another Example of Random Phase Plate

4.4.1 Example 2 of Random Phase Plate

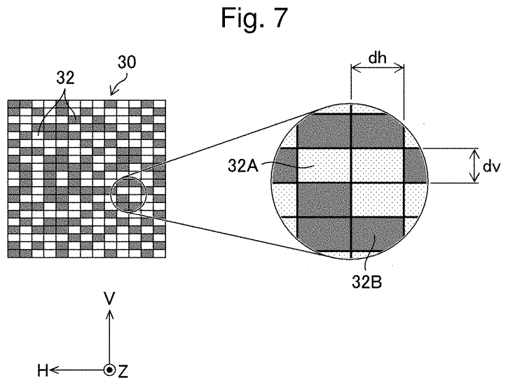

FIG. 7 is a diagrammatic front view of another example of the random phase plate 30. FIG. 7 shows an example of a square cell 32. In place of the random phase plate 30 in FIG. 4, the random phase plate 30 in FIG. 7 may be used. In FIG. 7, the same or similar components as in FIG. 4 are denoted by the same reference numerals, and descriptions thereof are omitted.

As shown in FIG. 7, the cell 32 may be rectangular with the length in the H direction being dh and the length in the V direction being dv. A preferable range of the aspect ratio (dh/dv) of the cell 32 and a preferable range of the size of the cell 32 in the example in FIG. 7 are the same as those in FIG. 4.

4.4.2 Shape of Cell

The cell on the random phase plate 30 may have various shapes, not limited to the hexagon in FIG. 4 and the square in FIG. 7. The cell may have a polygonal shape with an aspect ratio of 1.2 or more. The cell may have various tessellatable shapes such that the cells of a single geometric shape can tessellate a plane without any gaps.

### 5. Embodiment 2

5.1 Configuration

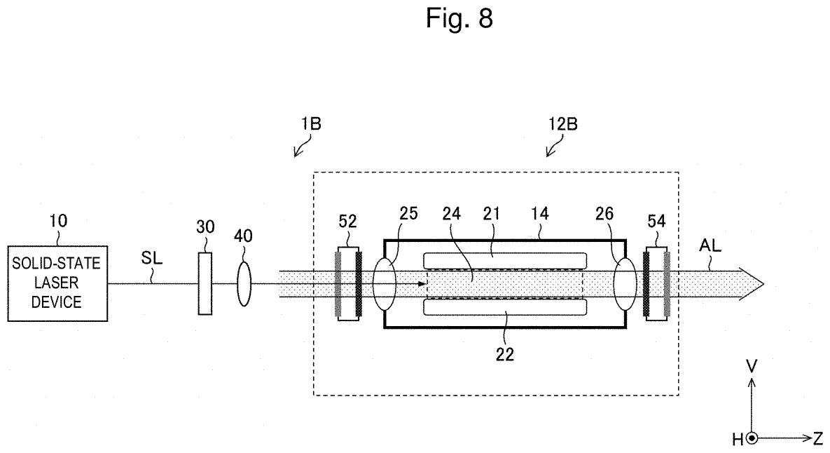

FIG. 8 schematically shows a configuration of a laser system 1B according to Embodiment 2. In Embodiment 2, the excimer amplifier 12 in Embodiment 1 is changed from the expanding three-pass amplifier to a Fabry-Perot (resonator) amplifier.

The laser system 1B in FIG. 8 includes an excimer amplifier 12B that is the Fabry-Perot amplifier. The excimer amplifier 12B includes a rear mirror 52, an output coupling mirror 54, and a chamber 14, and the chamber 14 is arranged between the rear mirror 52 and the output coupling mirror 54.

The rear mirror 52 and the output coupling mirror 54 are partially reflective mirrors that reflect part of the laser beam and transmit part of the laser beam. Reflectance of the rear mirror 52 is preferably higher than reflectance of the output coupling mirror 54. The reflectance of the rear mirror 52 is, for example, 80% to 90%. The rear mirror 52 and the output coupling mirror 54 constitute an optical resonator. The excimer amplifier 12B is an example of “Fabry-Perot resonator” in the present disclosure.

5.2 Operation

The seed light SL output from the solid-state laser device 10 and having the wavelength of about 193.4 nm enters the excimer amplifier 12B via the random phase plate 30 and the convex lens 40. The random phase plate 30 changes the beam profile and the beam divergence as in Embodiment 1.

The seed light SL having passed through the rear mirror 52 enters the discharge space 24 through the window 25. The seed light SL is amplified by the optical resonator constituted by the output coupling mirror 54 and the rear mirror 52, and the amplified laser beam AL is emitted from the output coupling mirror 54. The amplified laser beam AL emitted from the output coupling mirror 54 enters an exposure apparatus (not shown in FIG. 8).

5.3 Effect

The laser system 1B according to Embodiment 2 also provides the same effect as in Embodiment 1. Specifically, the random phase plate 30 provides different diffracting angles in the V direction and the H direction, thereby allowing change of the length-to-width ratio of the beam divergence. This allows the beam characteristic of the laser beam to be close to the beam characteristic of the current excimer laser beam.

### 6. Embodiment 3

6.1 Configuration

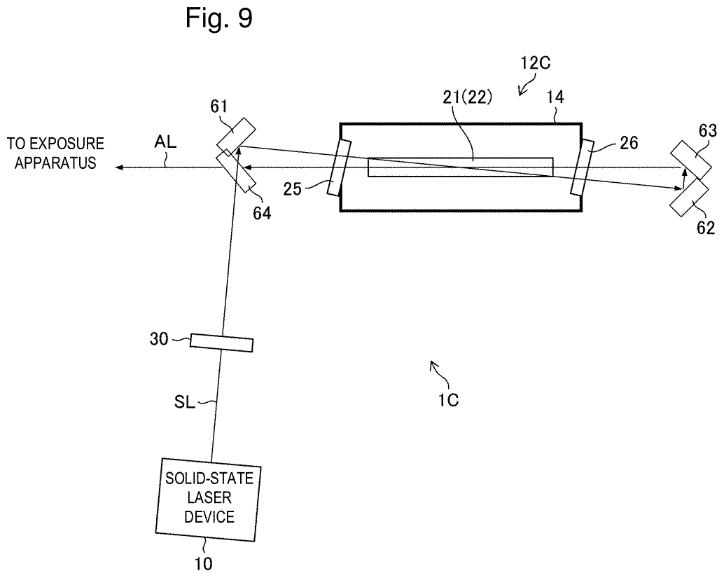

FIG. 9 schematically shows a configuration of a laser system 1C according to Embodiment 3. In Embodiment 3, the excimer amplifier 12 in Embodiment 1 is changed from the expanding three-pass amplifier to a ring resonator amplifier.

The laser system 1C in FIG. 9 includes an excimer amplifier 12C that is a ring resonator amplifier. The excimer amplifier 12C includes a chamber 14, a pair of discharge electrodes 21, 22, highly reflective mirrors 61, 62, 63, and an output coupling mirror 64. The output coupling mirror 64 is a partially reflective mirror that transmits part of the laser beam and reflects part of the laser beam.

The discharge electrodes 21, 22 are arranged to face each other with a space therebetween in a direction perpendicular to the plane of FIG. 9.

The output coupling mirror 64 and the highly reflective mirrors 61, 62, 63 constitute a ring resonator. In the laser system 1C according to Embodiment 3, a beam image forming position of an output coupler (not shown) of the solid-state laser device 10 is near the output coupling mirror 64, and the convex lens 40 described with reference to FIG. 3 is unnecessary.

6.2 Operation

The seed light SL output from the solid-state laser device 10 enters the output coupling mirror 64 of the excimer amplifier 12C via the random phase plate 30. The random phase plate 30 changes the beam profile and the beam divergence as in Embodiment 1.

Part of the seed light SL having entered the output coupling mirror 64 passes through the output coupling mirror 64 and is reflected by the highly reflective mirror 61. The seed light SL reflected by the highly reflective mirror 61 passes through the window 25 and travels to the discharge space 24 between the discharge electrodes 21, 22.

When the seed light SL exists in the discharge space 24, control to cause discharge in the discharge space 24 is performed to amplify the seed light SL. The amplified laser beam is emitted from the chamber 14 through the window 26. The laser beam emitted through the window 26 is highly reflected by the highly reflective mirrors 62, 63, again travels through the window 26 to the discharge space 24 in the chamber 14, and is amplified. The amplified laser beam is emitted from the chamber 14 through the window 25. The amplified laser beam emitted from the window 25 enters the output coupling mirror 64. Part of the amplified laser beam having entered the output coupling mirror 64 passes through the output coupling mirror 64 and is emitted from the excimer amplifier 12C as the amplified laser beam AL. The other part of the amplified laser beam having entered the output coupling mirror 64 is reflected by the output coupling mirror 64, and returned as feedback light to the ring optical resonator.

6.3 Effect

The laser system 1C according to Embodiment 3 also provides the same effect as in Embodiment 1.

### 7. Embodiment 4

7.1 Configuration

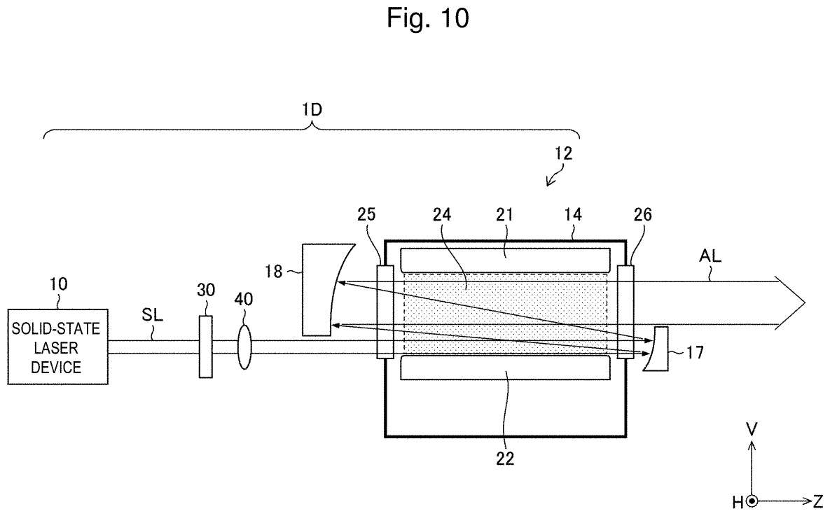

FIG. 10 schematically shows a configuration of a laser system 1D according to Embodiment 4. In the laser system 1D according to Embodiment 4, the convex cylindrical mirror 16 in the excimer amplifier 12 in FIG. 3 is changed to a concave cylindrical mirror 17. Other configurations are the same as those of the laser system 1A described with reference to FIG. 3.

The concave cylindrical mirror 17 is an example of “first mirror” and “concave mirror” in the present disclosure.

7.2 Operation

There may be a case that beam divergence significantly increases depending on the size of the cell 32 on the random phase plate 30. The concave cylindrical mirror 17 is used to adjust the divergence.

7.3 Effect

The laser system 1D according to Embodiment 4 can adjust the beam divergence using the concave cylindrical mirror 17, and allow the beam to appropriately pass through the optical system in the excimer amplifier 12.

### 8. Electronic Device Manufacturing Method

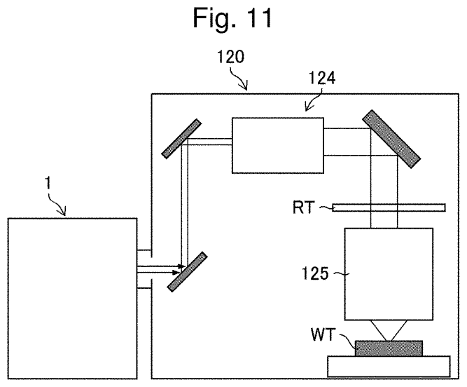

FIG. 11 schematically shows an exemplary configuration of an exposure apparatus 120. In FIG. 11, the exposure apparatus 120 includes an illumination optical system 124 and a projection optical system 125. The illumination optical system 124 illuminates, with a laser beam incident from the laser system 1, a reticle pattern on a reticle stage RT. The projection optical system 125 reduces and projects the laser beam having passed though the reticle and forms an image thereof on a workpiece (not shown) arranged on a workpiece table WT. The workpiece is a photosensitive substrate such as a semiconductor wafer coated with photoresist. The exposure apparatus 120 synchronously translates the reticle stage RT and the workpiece table WT to expose the laser beam reflecting the reticle pattern onto the workpiece. Through the exposure process as described above, a device pattern is transferred onto the semiconductor wafer, thereby manufacturing a semiconductor device. The semiconductor device is an example of “electronic device” in the present disclosure. The laser system 1 may be the laser system 1A, 1B, 1C, or 1D described in the embodiments.

### 9. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious for those skilled in the art that embodiments of the present disclosure would be appropriately combined.

The terms used throughout the present specification and the appended claims should be interpreted as non-limiting terms. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of the any thereof and any other than A, B, and C.

What is claimed is:

1. A laser system comprising:
a solid-state laser device configured to output a laser beam;
an excimer amplifier including a pair of discharge electrodes arranged to face each other with a discharge space therebetween, the laser beam passing through the discharge space, the excimer amplifier being configured to amplify the laser beam; and
a random phase plate arranged in an optical path between the solid-state laser device and the excimer amplifier,
cells of a predetermined shape being periodically arranged on the random phase plate, each cell being a minimum unit region of an irregular pattern that provides a phase difference to the laser beam, regions of depressions or projections in units of the cells being randomly arranged,
when a traveling direction of the laser beam entering the excimer amplifier is a Z direction, a discharge direction of the discharge electrodes is a V direction, a direction orthogonal to the V direction and the Z direction is an H direction, an in-plane direction of the random phase plate corresponding to the V direction of a beam section of the laser beam entering the excimer amplifier is a first direction, an in-plane direction of the random phase plate corresponding to the H direction of the beam section is a second direction, a length of the cell in the first direction is d1, and a length of the cell in the second direction is d2, an aspect ratio of the cell defined by d2/d1 being 1.2 or more.

2. The laser system according to claim 1, wherein the predetermined shape is a polygon.

3. The laser system according to claim 2, wherein the predetermined shape is a hexagon.

4. The laser system according to claim 2, wherein the predetermined shape is a square.

5. The laser system according to claim 1, wherein the aspect ratio is 1.2 or more and 5.0 or less.

6. The laser system according to claim 5, wherein the aspect ratio is 2.0 or more and 3.0 or less.

7. The laser system according to claim 1, wherein the length d2 is 20 μm or more and 500 μm or less.

8. The laser system according to claim 1, wherein the excimer amplifier is a three-pass amplifier that allows the laser beam to pass three times through the discharge space to amplify the laser beam.

9. The laser system according to claim 8, wherein
the excimer amplifier includes a first mirror and a second mirror facing each other with the discharge space therebetween, and
the first mirror that the laser beam having passed through the discharge space first enters is a convex mirror.

10. The laser system according to claim 8, wherein
the excimer amplifier includes a first mirror and a second mirror facing each other with the discharge space therebetween, and
the first mirror that the laser beam having passed through the discharge space first enters is a concave mirror.

11. The laser system according to claim 1, wherein the excimer amplifier is a Fabry-Perot resonator.

12. The laser system according to claim 1, wherein the excimer amplifier is a ring resonator.

13. The laser system according to claim 1, further comprising a light condensing optical system in an optical path between the random phase plate and the excimer amplifier.

14. The laser system according to claim 1, wherein
the predetermine shape is a tessellatable shape, and
the random phase plate is divided into regions in units of the cells without any gaps such that the cells are periodically arranged in the first direction and the second direction to tessellate a plane.

15. The laser system according to claim 1, wherein the phase difference is a phase difference between a beam passing through the depression and a beam passing through the projection, and is π radian.

16. The laser system according to claim 1, wherein
the random phase plate has a structure in which a film is arranged on a surface of a light transmissive substrate, and
a thickness of the film provides the phase difference.

17. The laser system according to claim 16, wherein a material for the light transmissive substrate is at least one of synthetic quartz, crystal, and calcium fluoride.

18. The laser system according to claim 16, wherein a material for the film is at least one of SiO₂, MgF₂, AlF₃, Na₃AlF₆, Na₅Al₃F₁₄, GdF₂, GdF₃, LaF₃, LaF₂, NdF₃, DyF₃, and YF₃.

19. An electronic device manufacturing method comprising:
generating an excimer laser beam with a laser system, the laser system including a solid-state laser device configured to output a laser beam, an excimer amplifier including a pair of discharge electrodes arranged to face each other with a discharge space therebetween, the laser beam passing through the discharge space, the excimer amplifier being configured to amplify the laser beam, and a random phase plate arranged in an optical path between the solid-state laser device and the excimer amplifier, cells of a predetermined shape being periodically arranged on the random phase plate, each cell being a minimum unit region of an irregular pattern that provides a phase difference to the laser beam, regions of depressions or projections in units of the cells being randomly arranged, when a traveling direction of the laser beam entering the excimer amplifier is a Z direction, a discharge direction of the discharge electrodes is a V direction, a direction orthogonal to the V direction and the Z direction is an H direction, an in-plane direction of the random phase plate corresponding to the V direction of a beam section of the laser beam entering the excimer amplifier is a first direction, an in-plane direction of the random phase plate corresponding to the H direction of the beam section is a second direction, a length of the cell in the first direction is d1, and a length of the cell in the second direction is d2, an aspect ratio of the cell defined by d2/d1 being 1.2 or more;
outputting the excimer laser beam to an exposure apparatus; and
exposing the excimer laser beam onto a photosensitive substrate within the exposure apparatus to manufacture an electronic device.
